(19) United States
(12) Patent Application Publication
(10) Pub. No.: US 2002/0113252 A1
(43) Pub. Date: Aug. 22, 2002

(54) Data carrier having means for communicating the value of its d.c. supply voltage to a communication station

(76) Inventor: Thomas Burger, Graz (AT)

Correspondence Address: U.S. Philps Corporation, 580 White Plains Road, Tarrytown, NY, 10591, US

(21) Appl. No.: 10/039,689

(22) Filed: Oct. 29, 2001

(30) Foreign Application Priority Data
Oct. 31, 2000 (EP) 00890324.7

(51) Int. Cl. H01L 31/072

(52) U.S. Cl. 257/200

(57) ABSTRACT

A data carrier (1) for the contactless communication with a communication station includes an integrated circuit (3), which includes a voltage generation circuit (7) by means of which a d.c. supply voltage (V) can be generated from a communication signal (CS(f₀)), which integrated circuit (3) in addition includes first switching means (22) with the aid of which a representation signal (REPS) corresponding to the amplitude value of the generated d.c. supply voltage (V), which integrated circuit (3) includes second switching means (28) with the aid of which the representation signal (REPS) can be transmitted to the communication station.

The invention relates to a data carrier for the contactless communication with a communication station, by means of which communication station a communication signal can be generated, which can be transmitted to the data carrier in a contactless manner, which data carrier includes an integrated circuit, which integrated circuit includes a voltage generation circuit to which the communication signal can be applied and which is adapted to generate a d.c. supply voltage with the aid of the communication signal.

The invention relates to an integrated circuit for a data carrier for the contactless communication with a communication station, by means of which communication station a communication signal can be generated, which can be transmitted to the data carrier in a contactless manner, which integrated circuit includes a voltage generation circuit to which the communication signal can be applied and which is adapted to generate a d.c. supply voltage with the aid of the communication signal.

Such a data carrier, of the type defined in the first paragraph, and such an integrated circuit for a data carrier, of the type defined in the second paragraph, are known from, for example, the patent document U.S. Pat. No. 5,345,231 A. The data carrier and the integrated circuit for the data carrier of the known types do not include means by which it is possible to communicate the value of the d.c. supply voltage generated with the aid of the voltage generation circuit to a communication station. This restricts the potential uses of such a record carrier and such an integrated circuit for such an record carrier, which is a disadvantage.

It is an object of the invention to eliminate the aforementioned restrictions and to realize an improved data carrier and an improved integrated circuit for a data carrier.

In order to achieve the aforementioned object, characteristic features in accordance with the invention are provided in a data carrier of the type defined in the first paragraph, in such a manner that a data carrier in accordance with the invention can be characterized in the manner defined hereinafter, namely:

A data carrier for the contactless communication with a communication station, by means of which communication station a communication signal can be generated, which can be transmitted to the data carrier in a contactless manner, which data carrier includes an integrated circuit, which integrated circuit includes a voltage generation circuit to which the communication signal can be applied and which is adapted to generate a d.c. supply voltage with the aid of the communication signal and in which at least one electrical quantity which determines the amplitude value of the d.c. supply voltage appears, and which integrated circuit in addition includes first switching means to which at least one representation value representative of said electrical quantity can be applied and which switching means are adapted to generate a representation signal representative of the amplitude value of the at least one representation value and which integrated circuit includes second switching means with the aid of which the representation signal can be transmitted to the communication station.

In order to achieve the aforementioned object, characteristic features in accordance with the invention are provided in an integrated circuit of the type defined in the second paragraph, in such a manner that an integrated circuit in accordance with the invention can be characterized in the manner defined hereinafter, namely:

An integrated circuit for data carrier for the contactless communication with a communication station, by means of which communication station a communication signal can be generated, which can be transmitted to the data carrier in a contactless manner, which integrated circuit includes a voltage generation circuit to which the communication signal can be applied and which is adapted to generate a d.c. supply voltage with the aid of the communication signal and in which at least one electrical quantity which determines the amplitude value of the d.c. supply voltage appears, and which integrated circuit in addition includes first switching means to which at least one representation value representative of said electrical quantity can be applied and which switching means are adapted to generate a representation signal representative of the amplitude value of the at least one representation value and which integrated circuit includes second switching means with the aid of which the representation signal can be transmitted to the communication station.

As a result of the provision of the characteristic features in accordance with the invention it is achieved in a comparatively simple and reliable manner, which can be activated or automated, that the amplitude value of the d.c. supply voltage which during operation occurs in a data carrier in accordance with the invention or in an integrated circuit, in accordance with the invention, for a data carrier can be transmitted to a communication station and can thus be evaluated with the aid of the communication station and can consequently be employed for various uses of the communication station and the data carrier.

A data carrier in accordance with the invention and an integrated circuit in accordance with the invention may include a carrier signal generator which during operation generates a carrier signal which is subjected to an amplitude modulation or a phase modulation in dependence on the amplitude value of the d.c. supply voltage, as a result of which the amplitude value or the phase value of the carrier signal represents the amplitude value of the d.c. supply voltage. However, it has proved to be particularly advantageous when the first switching means include an analog-to-digital converter, with the aid of which the amplitude value of the d.c. supply voltage and/or the amplitude value of a limiting voltage, which is proportional to a limiting current which flows through a voltage limiting stage, can be converted into at least one digital value, which at least one digital value forms the representation signal and can be transmitted to a communication station as a digital value. This embodiment has the advantage that the instantaneous absolute value of the d.c. supply voltage can be communicated from the relevant data carrier to a communication station.

It has proved to be very advantageous when a data carrier in accordance with the invention and an integrated circuit in accordance with the invention in addition include command evaluation means, because this enables the value of the d.c. supply voltage in the data carrier or in the integrated circuit to be interrogated in a precisely predetermined manner.

It has proved to be particularly advantageous when a data carrier in accordance with the invention and an integrated circuit in accordance with in addition have the possibility of transmitting an amplitude value of the d.c. supply voltage to a communication station when the d.c. supply voltage is limited with the aid of a voltage limiting stage, because in this way a communication station is also informed about the magnitude of the d.c. supply voltage in a data carrier and in an integrated circuit for a data carrier if the data carrier and the integrated circuit are very close to the relevant communication station, the voltage limiting stage then providing voltage limitation to a maximum permissible value and thereby precluding an excessive d.c. supply voltage in the data carrier and in the integrated circuit.

The above-mentioned as well as further aspects of the invention will become apparent from the embodiments described hereinafter by way of example and will be elucidated with reference to these examples.

The invention will now be described in more detail with reference to the drawings, which show three embodiments which are given by way of example but to which the invention is not limited.

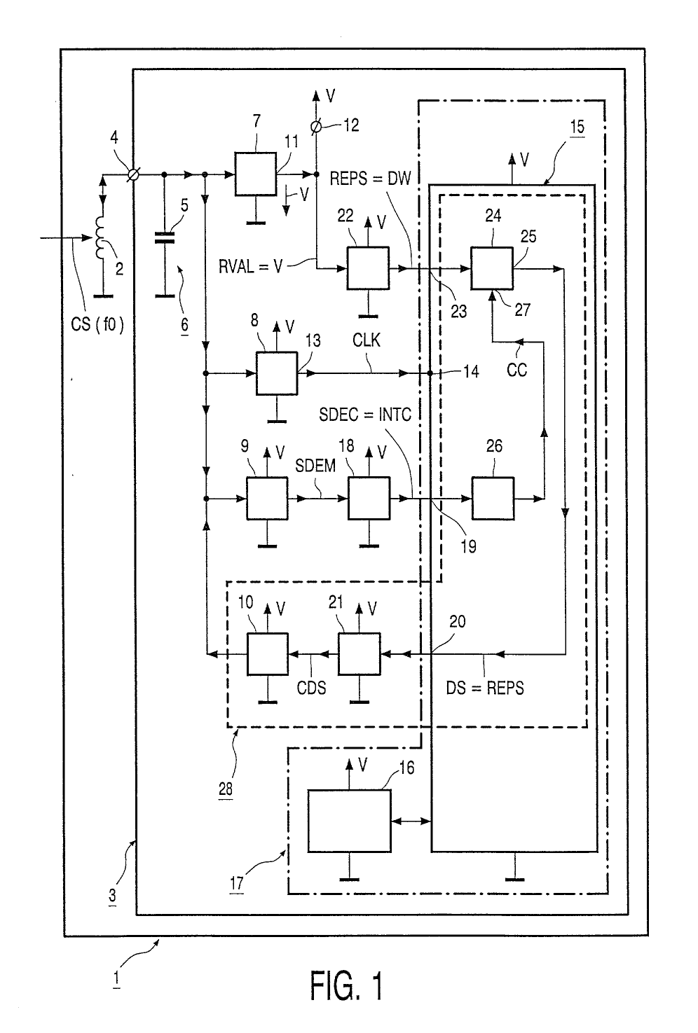

FIG. 1 is a block diagram which shows diagrammatically a relevant part of a data carrier embodying the invention.

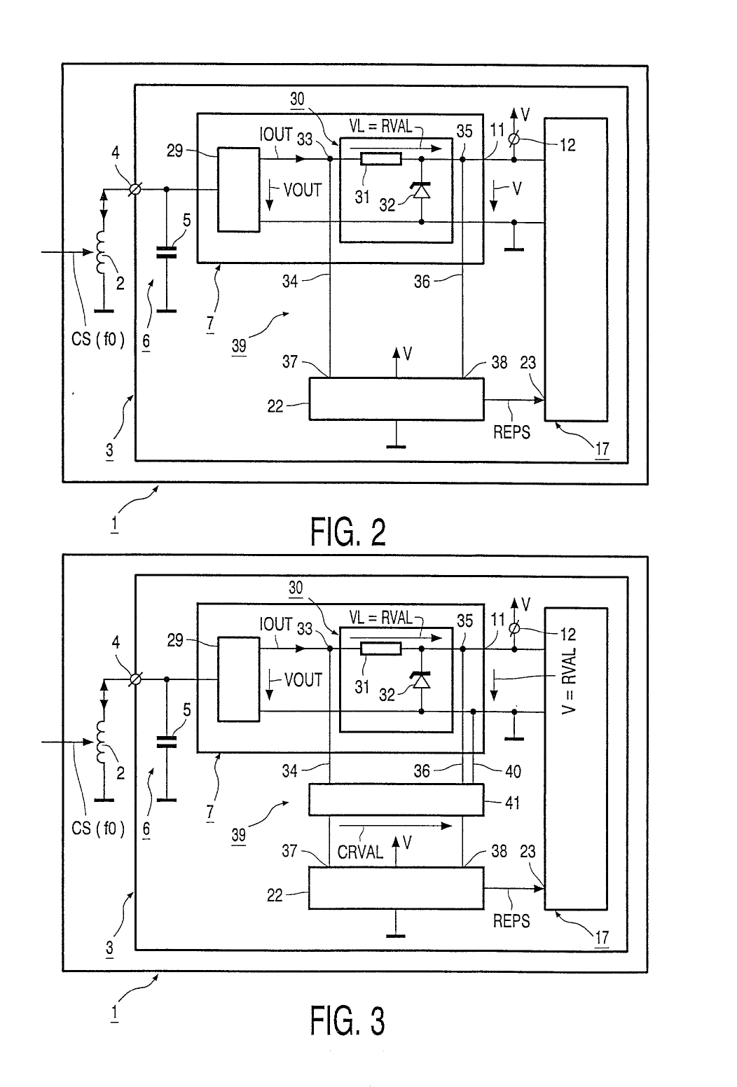

FIG. 2 shows, in a manner similar to FIG. 1, a part of a data carrier in accordance with a second embodiment of the invention.

FIG. 3 shows, in a manner similar to FIGS. 1 and 2, a part of a data carrier in accordance with a third embodiment of the invention.

FIG. 1 shows a data carrier 1. The data carrier 1 is adapted to provide contactless communication with a communication station, which is not shown in FIG. 1 because its structure is not relevant in the present context and which may for example have a structure as disclosed in the aforementioned patent document U.S. Pat. No. 5,345,231 A. The communication station can generate a communication signal CS(f₀), which communication signal is a carrier signal which takes the form of a sinewave signal and which has a frequency f₀. The communication signal CS(f₀) can be transmitted to the data carrier 1 in a contactless manner, namely either in amplitude-modulated form, in order to transmit data from the communication station to the data carrier 1, or in non-modulated form, so as to be subjected to a load modulated with the aid of the data carrier 1, in order to transmit data from the data carrier 1 to the communication station. The data carrier 1 includes a transmission coil 2, with the aid of which the communication signal CS(F₀) can be received inductively.

The data carrier 1 further includes an integrated circuit 3. The integrated circuit 3 has a terminal 4 connected to the transmission coil 2. The integrated circuit 3 includes a capacitor 5, which is likewise connected to the terminal 4 and which together with the transmission coil 2 forms a parallel resonant circuit 6 whose resonant frequency corresponds to the frequency fo of the communication signal CS(F₀).

The integrated circuit 3 includes a voltage generation circuit 7 and a clock signal regeneration circuit 8 as well as demodulation means 9 and modulation means 10. The aforementioned parts 7, 8, 9 and 10 are each connected to the terminal 4 of the integrated circuit 3.

The communication signal CS(F₀) can be applied to the voltage generation circuit 7. The voltage generation circuit 7 is adapted to generate a d.c. supply voltage V with the aid of the communication signal CS(F₀). Such a voltage generation circuit 7 is known in many variants, for which reason its circuit design will not be described in any further detail. The voltage generation circuit 7 is basically formed by a rectifier circuit. In the voltage generation circuit 7 an electrical quantity occurs, which determines the amplitude value of the d.c. supply voltage V and which, in the present case, is formed by the output voltage V appearing on the output 11 of the voltage generation circuit 7. The d.c. supply voltage V generated with the aid of the voltage generation circuit 7 appears on a circuit point 12 of the integrated circuit 3 and can be applied from this circuit point 12 to all those parts of the integrated circuit 3 which require this d.c. supply voltage V.

The communication signal CS(F₀) can also be applied to the clock signal regeneration circuit 8. The clock signal regeneration circuit 8 is adapted to regenerate a clock signal CLK required in the data carrier 1 and in the integrated circuit 3. The clock signal regeneration circuit 8 produces the regenerated clock signal CLK on an output 13. The regenerated clock signal CLK can be applied to an input 14 of a microprocessor 15, which microprocessor 15 is included in the integrated circuit 3. Together with a main memory 16 the microprocessor 15 forms a microcomputer 17 by means of which a multitude of means and functions are realized, of which only two means will be explained hereinafter. Instead of the microcomputer 17 it is possible to use a hard-wired logic circuit.

The communication signal CS(F₀) can also be applied to the demodulation means 9. When the communication signal CS(F₀) has been amplitude-modulated the demodulation means 9 carry out an amplitude demodulation, which yields a demodulated signal SDEM. The demodulated signal SDEM is applied to the decoding means 18, which decode the demodulated signal SDEM and subsequently supply a decoded signal SDEC, which is applied to an input 19 of the microprocessor 15. The decoded signal SDEC can be, for example, a so-called interrogation command INTC, which interrogation command INTC will be discussed in more detail hereinafter.

With regard to the modulation means 10 the following is to be noted. The microprocessor 15 has an output 20 to which a digital signal DS available in the microprocessor 15 can be applied. The digital signal DS can be, for example, a representation signal REPS, which will be discussed in greater detail hereinafter. The digital signal DS available on the output 20 of the microprocessor 15 can be applied to encoding means 21, by means of which the digital signal DS can be encoded, for example using a Manchester code. After encoding has been carried out the encoding means 21 supply an encoded digital signal CDS to the modulation means 10. The modulation means 10 perform a load modulation on the communication signal CS(F₀), which has been transmitted to the data carrier 1 in a nonmodulated manner, which load modulation is effected in dependence on the encoded digital signal CDS. It is thus possible to transmit digital signals DS from the data carrier 1 to a communication station.

The integrated circuit 3 advantageously includes first switching means 22, to which a representation value RVAL can be applied, which representation value RVAL represents the amplitude value of the electrical quantity which determines the d.c. supply voltage V. In the present case, as already stated, the electrical quantity which determines the d.c. supply voltage V is formed by the output voltage V appearing on the output of the voltage generation circuit 7, as a result of which the representation value RVAL is also formed by the d.c. supply voltage V. However, the representation value RVAL need not be determined by the entire d.c. supply voltage but may alternatively be determined by a fraction of the d.c. supply voltage V. The first switching means 22 are adapted to generate a representation signal REPS representative of the amplitude value of the representation value RVAL, i.e. in the present case the amplitude value of the d.c. supply voltage V.

In the data carrier 1 and the integrated circuit 3 shown in FIG. 1 the first switching means 22 are formed by an analog-to-digital converter 22. With the aid of the analog-to-digital converter 22 a data word DW representative of the amplitude value of the d.c. supply voltage V can be generated as a representation signal REPS. The generated data word DW can be applied to a further input 23 of the microprocessor 15. Depending on the situation said word can be applied via a line connection or a bus connection. With the aid of the microprocessor 15 a buffer memory 24 is formed, which is connected to the further input 23 and by means of which the data word DW forming the representation signal REPS can be stored. The output 25 of the buffer memory 24 is connected to the output 20, as a result of which the data word DW stored in the buffer memory 24, i.e. the representation signal REPS, can be transferred from the buffer memory 24 to the output 20 of the microprocessor 15.

In addition, command evaluation means 26 are formed with the aid of the microprocessor 15. The command evaluation means 26 are adapted to receive and evaluate an interrogation command INTC supplied by a communication station and received with the aid of the transmission coil 2, which command is demodulated with the aid of the demodulation means 9 and is decoded with the aid of the decoding means 18. Such an interrogation command INTC is transmitted from a communication station to the data carrier 1, i.e. to the integrated circuit 1, if a data word DW stored in the buffer memory 24, i.e. the representation signal REPS representing the amplitude value of the d.c. supply voltage V, is to be read out or retrieved. As soon as an interrogation command INTC arrives at the command evaluation means 26 such an interrogation command INTC is received and evaluated, as a result of which the command evaluation means 26 generate a control command CC, which is applied to a control input 27 of the buffer memory 24 by the command evaluation means 26. As a result, the data word DW stored in the buffer memory 24, i.e. the stored representation signal REPS, is applied, via the output 20 of the microprocessor 15, to the encoding means 21 and, subsequently, to the modulation means 10, which results in the representation signal REPS being transmitted from the data carrier 1 to the communication station which has issued the interrogation command INTC. This means, in other words, that after having received and evaluated an interrogation command INTC the command evaluation means 26 cause the representation signal REPS to be transmitted from the data carrier 1 to a communication station.

In the data carrier 1 and its integrated circuit 3 the instantaneous amplitude value of the d.c. supply voltage V is applied to the analog-to-digital converter 22 and accordingly a representation signal REPS representing the instantaneous amplitude value, i.e. an instantaneous data word DW is generated, which is stored in the buffer memory 24 and which can be read from the buffer memory 24 and transmitted to a communication station when this is requested by the communication station with the aid of an interrogation command INTC. The buffer memory 24 and the command evaluation means 26 as well as the encoding means 21 and the modulation means 10 then form second switching means 28 of the integrated circuit 3, with the aid of which switching means the relevant representation signal REPS can be transmitted to the communication station. This has the advantage that the amplitude value of the d.c. supply voltage V which appears in the data carrier 1 and in the integrated circuit 3 during operation can be transmitted to a communication station and is thus available in the communication station and can consequently be evaluated in the communication station and can thus be employed for different potential uses of the communication station and of the data carrier 1.

In the data carrier 1 and in the integrated circuit 3 shown in FIG. 2 the voltage generation circuit 7 includes a voltage generation stage 29 and a voltage limiting stage 30, which follows the voltage generation stage 29. Such an arrangement has been known since long in different variants. The output voltage VOUT generated with the aid of the first voltage generation stage 29 and the output current IOUT supplied by the voltage generation stage 29 are applied to the voltage limiting stage 30. The voltage limiting stage 30 includes a series resistor 31, provided as current limiting resistor, and a zener diode 32. After voltage limiting the voltage limiting stage 30 produces on its output the d.c. supply voltage V, which in this case has been limited and which is applied to, inter alia, the microcomputer 17. An electrical quantity which determines the amplitude value of the d.c. supply voltage V also occurs in the embodiment shown in FIG. 2, which quantity in the present case is determined indirectly by the output current IOUT and is formed by a voltage VL produced across the series resistor 31, as a result of which it is proportional to the output current IOUT.

In the integrated circuit 3 shown in FIG. 2 an analog-to-digital converter 22, which serves as the first switching means 22, has an input 37 connected to a circuit point 33 situated before the series resistor 31 via a line 34 and has an input 38 connected to a circuit point 35 situated after the series resistor 31 via a line 36. The two lines 34 and 36 thus form means with the aid of which a voltage VL, which appears in the voltage limiting stage 30 and which is proportional to the output current IOUT in the voltage limiting stage 30, can be applied to the switching means 22, i.e. the analog-to-digital converter 22, as the representation value RVAL. Alternatively, only a fraction of the voltage VL can be used as the representation value RVAL, if this is advantageous.

Thus, in the embodiment shown in FIG. 2 the voltage VL, which is proportional to the output current IOUT and which determines the amplitude value of the d.c. supply voltage V, is applied to the analog-to-digital converter 22 as the representation value RVAL, after which the analog-to-digital converter 22 generates a representation signal REPS in a manner similar to that in the data carrier 1 shown in FIG. 1, which representation signal is applied to the microcomputer 17. In exactly the same way as in the data carrier 1 shown in FIG. 1, the representation signal REPS, which is subsequently stored in the microcomputer 17, can be read out with the aid of an interrogation command and can be transmitted to a communication station with the aid of second switching means (see FIG. 1, reference numeral 28) which are not shown in FIG. 2.

The embodiment of the data carrier 1 and of the integrated circuit 3 shown in FIG. 3 is a combination of the embodiments of the data carrier 1 shown in FIGS. 1 and 2 and of the integrated circuit 3 shown in FIGS. 1 and 2, respectively. The present embodiment employs both a voltage VL proportional to the output current IOUT as a representation value and the generated d.c. supply voltage V itself as a representation value. The two voltages VL and V are applied to a network 41 via the lines 34 and 36 and via an additionally provided line 40, which network 41 forms a combined representation value CRVAL, which is subsequently applied to the analog-to-digital converter 22 via its two inputs 37 and 38. With the aid of the analog-to-digital converter 22 the combined representation value CRVAL is converted into a representation signal REPS, which is applied to the microcomputer 17.

Instead of the network 41 and an analog-to-digital converter 22 it is possible to provide two separate analog-to-digital converters, of which one converter receives the voltage VL proportional to the output current IOUT and of which the other converter receives the d.c. supply voltage V as the respective representation value RVAL. Instead of the network 41 a multiplexer which is controllable by the microcomputer 17 may be provided, with the aid of which the voltage VL proportional to the output current IOUT and the d.c. supply voltage V can be applied selectively to an analog-to-digital converter as the respective representation value RVAL. In each case it is then possible to generate two mutually independent representation signals REPS with the aid of two analog-to-digital converters and one analog-to-digital converter, respectively, which signals can be transmitted separately to a communication station and can be processed separately or combined in this station.

The characteristic features in accordance with the invention for all the three data carriers 1 described hereinbefore and all the three integrated circuits 3 described hereinbefore have significant advantages. For example, when such a data carrier 1 is tested with the aid of the representation signal REPS transmitted to a test communication station it is very simple to obtain information about the range of the data carrier tested without the need to vary the power of the test communication station for this purpose. For example, with the aid of the representation signal REPS transmitted to a communication station it is also simple to determine how far a data carrier 1 is situated from a the communication station. In the case of a relative movement between a communication station and a data carrier 1 it is also simple to determine by a plurality of successive transmissions of a respective representation signal REPS whether the data carrier 1 is moving towards the communication station or is moving away from the communication station.

1. A data carrier (1) for the contactless communication with a communication station, by means of which communication station a communication signal (CS(F₀)) can be generated, which can be transmitted to the data carrier (1) in a contactless manner,
which data carrier (1) includes an integrated circuit (3),
which integrated circuit (3) includes a voltage generation circuit (7) to which the communication signal (CS(F₀)) can be applied and which is adapted to generate a d.c. supply voltage (V) with the aid of the communication signal (CS(F₀)) and in which at least one electrical quantity (V; VL) which determines the amplitude value of the d.c. supply voltage (V) appears, and
which integrated circuit (3) in addition includes first switching means (22) to which at least one representation value (RVAL; CRVAL) representative of said electrical quantity (V; VL) can be applied and which switching means are adapted to generate a representation signal (REPS) representative of the amplitude value of the at least one representation value (RVAL; CRVAL), and
which integrated circuit (3) includes second switching means (28) with the aid of which the representation signal (REPS) can be transmitted to the communication station.

2. A data carrier (1) as claimed in claim 1,
in which the first switching means (22) include an analog-to-digital converter.

3. A data carrier (1) as claimed in claim 1,
in which the integrated circuit (3) has command evaluation means (26) which are adapted to receive and evaluate an interrogation command (INTC) supplied by a communication station and which after reception and evaluation of such an interrogation command (INTC) cause the representation signal (REPS) to be transmitted from the data carrier (1) to this communication station.

4. A data carrier (1) as claimed in claim 1,
in which the voltage generation circuit (7) includes a voltage limiting stage (30), from which the d.c. supply voltage (V) can be taken, and
in which means (39) have been provided with the aid of which a voltage (VL) appearing in the voltage limiting stage (30) and proportional to a current (IOUT) in the voltage limiting stage (30) can be applied to the first switching means (22) as a representation value (RVAL).

5. An integrated circuit (3) for data carrier (1) for the contactless communication with a communication station, by means of which communication station a communication signal (CS(F₀)) can be generated, which can be transmitted to the data carrier (1) in a contactless manner,
which integrated circuit (3) includes a voltage generation circuit (7) to which the communication signal (CS(F₀)) can be applied and which is adapted to generate a d.c. supply voltage (V) with the aid of the communication signal (CS(F₀)) and in which at least one electrical quantity (V; VL) which determines the amplitude value of the d.c. supply voltage (V) appears, and
which integrated circuit (3) in addition includes first switching means (22) to which at least one representation value (RVAL; CRVAL) representative of said electrical quantity (V; VL) can be applied and which switching means are adapted to generate a representation signal (REPS) representative of the amplitude value of the at least one representation value (RVAL; CRVAL), and
which integrated circuit (3) includes second switching means (28) with the aid of which the representation signal (REPS) can be transmitted to the communication station.

6. An integrated circuit (3) as claimed in claim 5,
in which the first switching means (22) include an analog-to-digital converter.

7. An integrated circuit (3) as claimed in claim 5,
in which the integrated circuit (3) has command evaluation means (26) which are adapted to receive and evaluate an interrogation command (INTC) supplied by a communication station and which after reception and evaluation of such an interrogation command (INTC) cause the representation signal (REPS) to be transmitted from the data carrier (1) to this communication station.

8. An integrated circuit (3) as claimed in claim 5,
in which the voltage generation circuit (7) includes a voltage limiting stage (30), from which the d.c. supply voltage (V) can be taken, and
in which means (39) have been provided with the aid of which a voltage (VL) appearing in the voltage limiting stage (30) and proportional to a current (IOUT) in the voltage limiting stage (30) can be applied to the first switching means (22) as a representation value (RVAL).
